(19) United States
(12) Patent Application Publication
(10) Pub. No.: US 2016/0148686 A1
(43) Pub. Date: May 26, 2016

(54) MEMORY CELL ARRAY OF RESISTIVE RANDOM-ACCESS MEMORIES

(71) Applicant: eMemory Technology Inc., Hsin-Chu (TW)

(72) Inventors: Chia-Jung Hsu, Taoyuan City (TW); Wein-Town Sun, Taoyuan City (TW); Ching-Sung Yang, Hsinchu City (TW); Chi-Yi Shao, Taichung City (TW); Chun-Yuan Lo, Taipei City (TW); Yu-Hsiung Tsai, Hsinchu City (TW); Ching-Yuan Lin, Hsinchu County (TW)

(21) Appl. No.: 14/877,239

(22) Filed: Oct. 7, 2015

Related U.S. Application Data
(60) Provisional application No. 62/084,561, filed on Nov. 26, 2014.
(60) Provisional application No. 62/105,744, filed on Jan. 21, 2015.

(51) Int. Cl. G11C 13/00

(52) U.S. Cl. CPC G11C 13/0069; G11C 13/004; G11C 13/0097

(57) ABSTRACT

A memory cell array includes a first bit line, a first word line, a first source line pair and a first memory cell. A select terminal of the first memory cell is connected with the first word line. A first control terminal of the first memory cell is connected with a first source line of the first source line pair. A second control terminal of the first memory cell is connected with a second source line of the first source line pair. A third control terminal of the first memory cell is connected with the first bit line.

This application claims the benefits of U.S. provisional application Ser. No. 62/084,561, filed Nov. 26, 2014 and No. 62/105,744, filed Jan. 21, 2015, the subject matters of which are incorporated herein by reference.

### FIELD OF THE INVENTION

The present invention relates to a memory, and more particularly to a memory cell array of resistive random-access memories.

### BACKGROUND OF THE INVENTION

A resistive random-access memory (RRAM) is one kind of non-volatile memory. Since the resistive random-access memories have larger storage capability and higher accessing speed, the manufacturers of the memories pay much attention to the development of the resistive random-access memories.

FIG. 1 schematically illustrates the structure of a resistive random-access memory. As shown in FIG. 1, the resistive random-access memory 100 comprises a top electrode 102, an insulation layer 104 and a bottom electrode 106. After the resistive random-access memory is fabricated, the resistive random-access memory is in an initial state.

Before the operation of the resistive random-access memory 100, a forming action is performed to apply a first voltage difference (e.g., +3V) to the top electrode 102 and the bottom electrode 106. For example, the top electrode 102 receives a voltage of +3V, and the bottom electrode 106 receives a ground voltage. While the forming action is performed, the cluster of oxygen vacancies in the insulation layer 104 forms a conducting filament 108. In addition, the conducting filament 108 is connected with the top electrode 102 and the bottom electrode 106. After the conducting filament 108 is formed, the forming action is completed. Meanwhile, the region between the top electrode 102 and the bottom electrode 106 has a low resistance value (i.e., in a set state). Consequently, the resistive random-access memory 100 can be normally operated.

Moreover, a reset action may be performed to switch the set state to a reset state (i.e., a high resistance value). While the reset action is performed, a second voltage difference (e.g., −3V) is applied to the top electrode 102 and the bottom electrode 106. For example, the top electrode 102 receives a voltage of −3V, and the bottom electrode 106 receives the ground voltage. After the reset action is completed, the conducting filament 108 within the insulation layer 104 is treated by a redox process. Consequently, the conducting filament 108 is no longer connected between the top electrode 102 and the bottom electrode 106. Meanwhile, the region between the top electrode 102 and the bottom electrode 106 has the high resistance value (i.e., in the reset state).

In case that the resistive random-access memory 100 is in the reset state, the resistive random-access memory 100 may be switched to the set state by a set action. While the set action is performed, a third voltage difference (e.g., +3V) is applied to the top electrode 102 and the bottom electrode 106. For example, the top electrode 102 receives a voltage of +3V, and the bottom electrode 106 receives the ground voltage. After the set action is completed, the region between the top electrode 102 and the bottom electrode 106 has the low resistance value (i.e., in the set state).

Consequently, in response to a program action during a program cycle, the resistive random-access memory 100 can be selectively programmed in the set state through the set action or in the reset state through the rest action. In other words, the set state and the reset state are two storing states of the resistive random-access memory 100.

Moreover, in response to a read action during a read cycle, a read voltage (e.g., 0.1V˜0.5V) is applied to the top electrode 102 and the bottom electrode 106. Consequently, according to the magnitude of a read current generated by the resistive random-access memory 100, the storing state (i.e., the set state or the reset state) of the resistive random-access memory 100 can be realized.

FIG. 2 is a schematic circuit diagram illustrating a memory cell array of a conventional resistive random-access memory. As shown in FIG. 2, the memory cell array 200 of the resistive random-access memory comprises plural memory cells. The plural memory cells are connected with word lines WL0˜WL3, bit lines BL0˜BL3 and source lines SL0˜SL3.

Take the memory cell 210 as an example. The memory cell 210 comprises a select transistor M and a resistor R. A select terminal of the select transistor M is connected with the word line WL0. A first terminal of the select transistor M is connected with the bit line BL0. The resistor R is connected between the source line SL0 and a second terminal of the select transistor M. The resistor R has the structure of the resistive random-access memory 100 as shown in FIG. 1.

Generally, the memory cell array 200 is connected with a controlling circuit (not shown). The controlling circuit can active one of the word lines WL0˜WL3 to determine a selected memory cell. Moreover, the controlling circuit may perform the forming action, the program action or the read action on the selected memory cell.

For example, when the word line WL0 is activated and the memory cell 210 is determined as the selected memory cell, the controlling circuit may perform the forming action on the memory cell 210. That is, by applying the first voltage difference (e.g., +3V) to the source line SL0 and the bit line BL0, the resistor R is in the set state.

Moreover, in response to a program action during a program cycle, the controlling circuit may perform the reset action on the memory cell 210. That is, by applying the second voltage difference (e.g., −3V) to the source line SL0 and the bit line BL0, the resistor R is in the reset state.

Alternatively, in response to the program action during the program cycle, the controlling circuit may perform the set action on the memory cell 210. That is, by applying the third voltage difference (e.g., +3V) to the source line SL0 and the bit line BL0, the resistor R is in the set state.

Moreover, in response to a read action during a read cycle, the controlling circuit provides a read voltage (e.g., 0.1V˜0.5V) to the source line SL0 and the bit line BL0. Consequently, according to the magnitude of a read current flowing through the bit line BL0, the storing state (i.e., the set state or the reset state) of the memory cell 210 can be realized by the controlling circuit.

However, since the fabricating process is usually unstable, the reliability of the memory cell array 100 is not satisfied. Since the variation of the low resistance value in the set state is very large, the change of the magnitude of the read current is large. In other words, the controlling circuit cannot accurately judge the storing state according to the magnitude of the read current.

### SUMMARY OF THE INVENTION

The present invention provides a memory cell array of resistive random-access memories. The memory cell array comprises at least two resistive random-access memories and at least one switch transistor. Consequently, during the read cycle, the storing state of the memory cell can be judged more accurately.

An embodiment of the present invention provides a memory cell array. The memory cell array includes a first bit line, a first word line, a first source line pair and a first memory cell. A select terminal of the first memory cell is connected with the first word line. A first control terminal of the first memory cell is connected with a first source line of the first source line pair. A second control terminal of the first memory cell is connected with a second source line of the first source line pair. A third control terminal of the first memory cell is connected with the first bit line. The first memory cell includes a select transistor, a first resistor and a second resistor. The select transistor includes a gate terminal, a first source/drain terminal and a second source/drain terminal. The gate terminal of the select transistor is connected with the select terminal of the first memory cell. The first source/drain terminal of the select transistor is connected with the third control terminal of the first memory cell. A first terminal of the first resistor is connected with the second source/drain terminal of the select transistor of the first memory cell. A second terminal of the first resistor is connected with the first control terminal of the first memory cell. A first terminal of the second resistor is connected with the second source/drain terminal of the select transistor of the first memory cell. A second terminal of the second resistor is connected with the second control terminal of the first memory cell.

Another embodiment of the present invention provides a memory cell array. The memory cell array includes a first bit line pair, a first word line, a first source line and a first memory cell. A select terminal of the first memory cell is connected with the first word line. A first control terminal of the first memory cell is connected with a first bit line of the first bit line pair. A second control terminal of the first memory cell is connected with a second bit line of the first bit line pair. A third control terminal of the first memory cell is connected with the first source line. The first memory cell includes a select transistor, a first resistor and a second resistor. The select transistor includes a gate terminal, a first source/drain terminal and a second source/drain terminal. The gate terminal of the select transistor is connected with the select terminal of the first memory cell. The first source/drain terminal of the select transistor is connected with the third control terminal of the first memory cell. A first terminal of the first resistor is connected with the second source/drain terminal of the select transistor of the first memory cell. A second terminal of the first resistor is connected with the first control terminal of the first memory cell. A first terminal of the second resistor is connected with the second source/drain terminal of the select transistor of the first memory cell. A second terminal of the second resistor is connected with the second control terminal of the first memory cell.

Another embodiment of the present invention provides a memory cell array. The memory cell array includes a first bit line, a first word line, a first source line and a first memory cell. A select terminal of the first memory cell is connected with the first word line. A first control terminal of the first memory cell is connected with the first source line. A second control terminal of the first memory cell is connected with the first source line. A third control terminal of the first memory cell is connected with the first bit line. The first memory cell includes a first select transistor, a first resistor, a second select transistor and a second resistor. The first select transistor includes a gate terminal, a first source/drain terminal and a second source/drain terminal. The gate terminal of the first select transistor is connected with the select terminal of the first memory cell. The first source/drain terminal of the first select transistor is connected with the third control terminal of the first memory cell. A first terminal of the first resistor is connected with the second source/drain terminal of the first select transistor of the first memory cell. A second terminal of the first resistor is connected with the first control terminal of the first memory cell. The second select transistor includes a gate terminal, a first source/drain terminal and a second source/drain terminal. The gate terminal of the second select transistor is connected with the select terminal of the first memory cell. The first source/drain terminal of the second select transistor is connected with the third control terminal of the first memory cell. A first terminal of the second resistor is connected with the second source/drain terminal of the second select transistor of the first memory cell. A second terminal of the second resistor is connected with the second control terminal of the first memory cell.

Another embodiment of the present invention provides a memory cell array. The memory cell array includes a first bit line, a first word line, a first source line pair and a first memory cell. A select terminal of the first memory cell is connected with the first word line. A first control terminal of the first memory cell is connected with a first source line of the first source line pair. A second control terminal of the first memory cell is connected with a second source line of the first source line pair. A third control terminal of the first memory cell is connected with the first bit line. The first memory cell includes a first select transistor, a first resistor, a second select transistor and a second resistor. The first select transistor includes a gate terminal, a first source/drain terminal and a second source/drain terminal. The gate terminal of the first select transistor is connected with the select terminal of the first memory cell. The first source/drain terminal of the first select transistor is connected with the third control terminal of the first memory cell. A first terminal of the first resistor is connected with the second source/drain terminal of the first select transistor of the first memory cell. A second terminal of the first resistor is connected with the first control terminal of the first memory cell. The second select transistor includes a gate terminal, a first source/drain terminal and a second source/drain terminal. The gate terminal of the second select transistor is connected with the select terminal of the first memory cell. The first source/drain terminal of the second select transistor is connected with the third control terminal of the first memory cell. A first terminal of the second resistor is connected with the second source/drain terminal of the second select transistor of the first memory cell. A second terminal of the second resistor is connected with the second control terminal of the first memory cell.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 (prior art) schematically illustrates the structure of a resistive random-access memory;

FIG. 2 (prior art) is a schematic circuit diagram illustrating a memory cell array of a conventional resistive random-access memory;

FIG. 3A is a schematic circuit diagram illustrating the structure of a memory cell of a resistive random-access memory according to a first embodiment of the present invention;

FIG. 3B is a schematic circuit diagram illustrating a first exemplary memory cell array with the memory cells of FIG. 3A;

FIG. 3C is a schematic circuit diagram illustrating a second exemplary memory cell array with the memory cells of FIG. 3A;

FIG. 3D is a schematic circuit diagram illustrating a third exemplary memory cell array with the memory cells of FIG. 3A;

FIG. 4A is a schematic circuit diagram illustrating the structure of a memory cell of a resistive random-access memory according to a second embodiment of the present invention;

FIG. 4B is a schematic circuit diagram illustrating a first exemplary memory cell array with the memory cells of FIG. 4A;

FIG. 4C is a schematic circuit diagram illustrating a second exemplary memory cell array with the memory cells of FIG. 4A;

FIG. 4D is a schematic circuit diagram illustrating a third exemplary memory cell array with the memory cells of FIG. 4A; and

FIG. 4E is a schematic circuit diagram illustrating a fourth exemplary memory cell array with the memory cells of FIG. 4A.

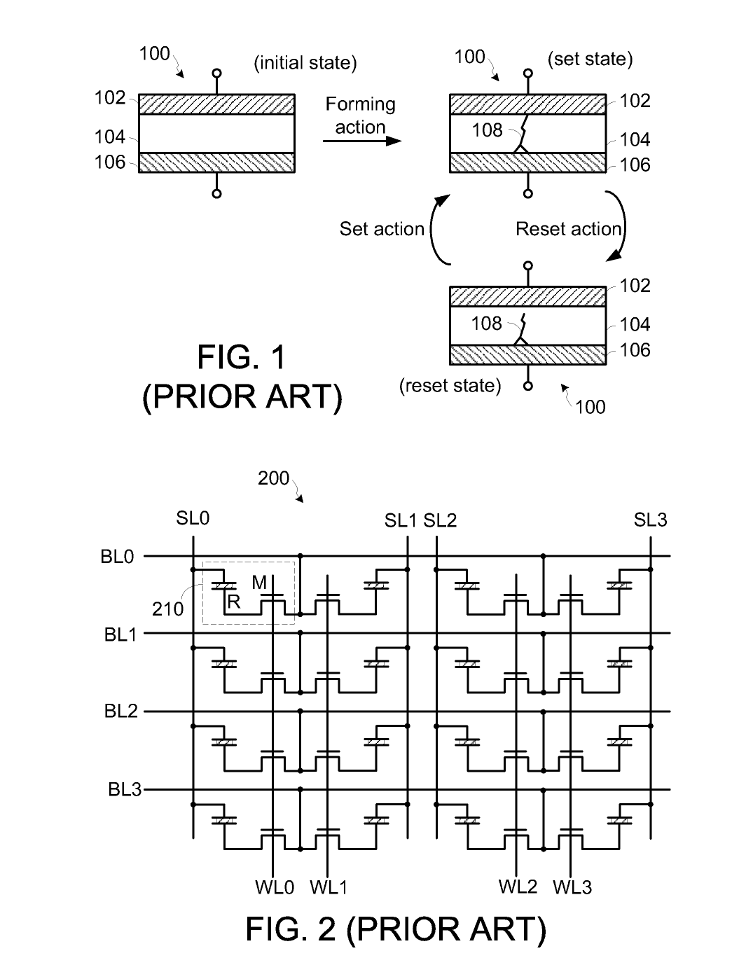

### DETAILED DESCRIPTION OF PREFERRED EMBODIMENTS

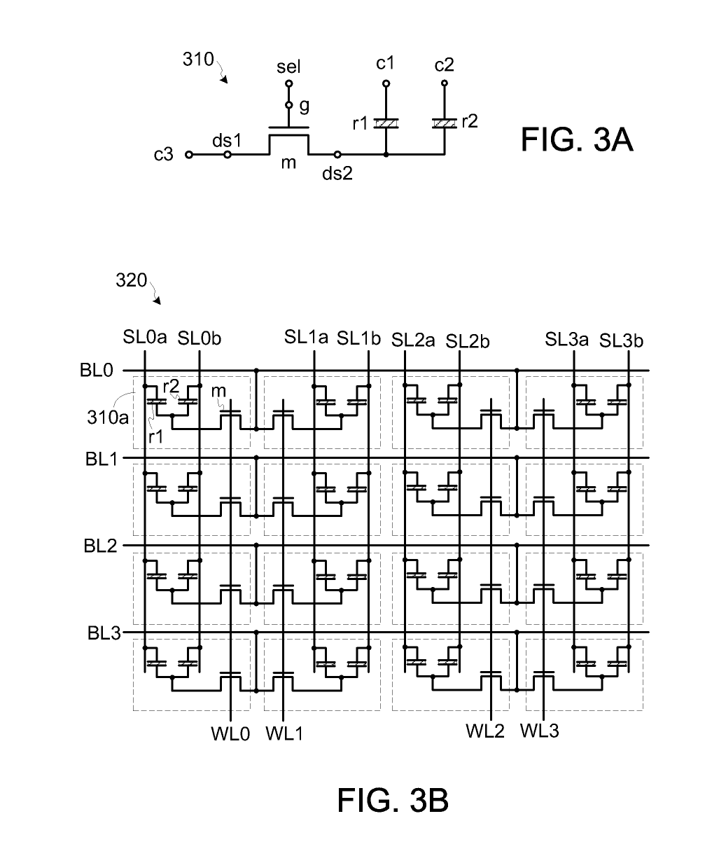

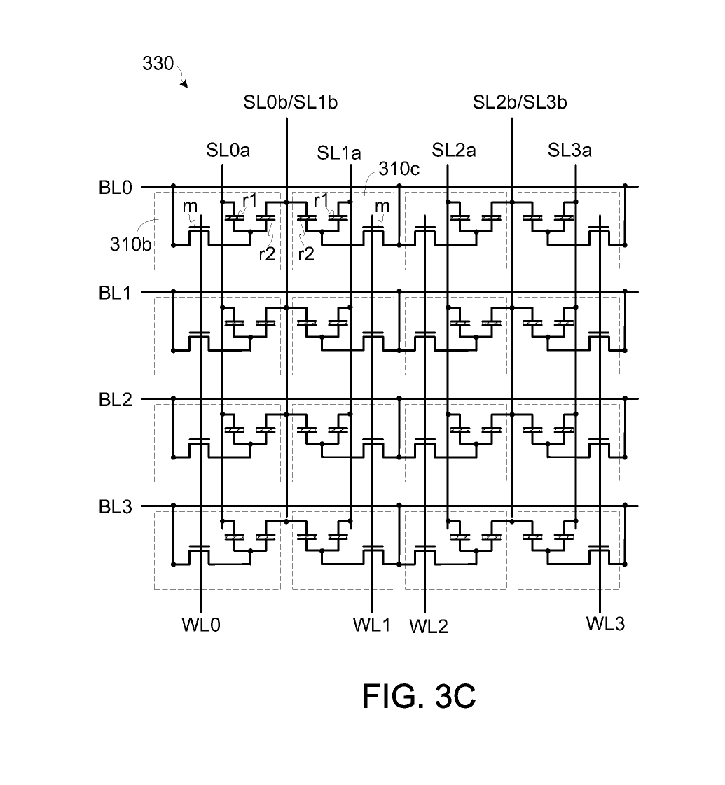

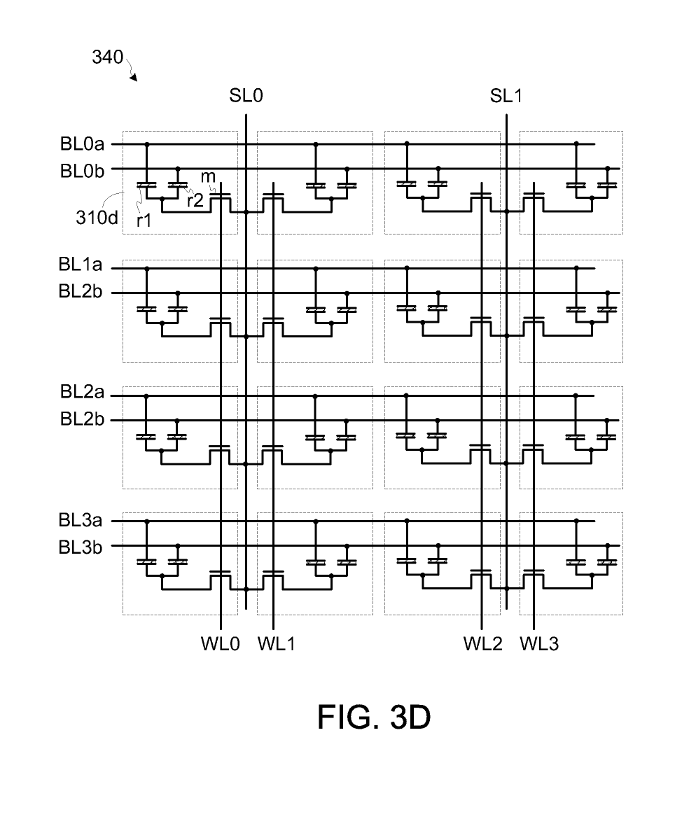

FIG. 3A is a schematic circuit diagram illustrating the structure of a memory cell of a resistive random-access memory according to a first embodiment of the present invention. As shown in FIG. 3A, the memory cell 310 comprises a select transistor m, a first resistor r1 and a second resistor r2. The select transistor m comprises a gate terminal g, a first source/drain terminal ds1 and a second source/drain terminal ds2. The gate terminal g is connected with a select terminal sel. The first resistor r1 is connected between a first control terminal c1 and the second source/drain terminal ds2. The second resistor r2 is connected between a second control terminal c2 and the second source/drain terminal ds2. The first source/drain terminal ds1 is connected with a third control terminal c3. In this embodiment, the first resistor r1 and the second resistor r2 have the structures of resistive random-access memories.

Moreover, plural memory cells 310 can be combined together as three types of memory cell arrays. The detailed structures of these memory cell arrays will be illustrated as follows.

FIG. 3B is a schematic circuit diagram illustrating a first exemplary memory cell array with the memory cells of FIG. 3A. As shown in FIG. 3B, the memory cells of the memory cell array 320 are arranged in a 4×4 array. Moreover, the memory cell array 320 is connected with word lines WL0˜WL3, bit lines BL0˜BL3, a first source line pair (SL0a, SL0b), a second source line pair (SL1a, SL01), a third source line pair (SL2a, SL2b), and a fourth source line pair (SL3a, SL3b).

Take the memory cell 310a as an example. The select terminal of the memory cell 310a is connected with the word line WL0. The third control terminal of the memory cell 310a is connected with the bit line BL0. The first control terminal and the second control terminal of the memory cell 310a are respectively connected with the source lines SL0a and SL0b of the first source line pair. The connecting relationships between other memory cells and the corresponding lines are similar to the connecting relationship between the memory cell 310a and the corresponding lines, and are not redundantly described herein.

The memory cell array 320 is connected with a controlling circuit (not shown). The controlling circuit can active one of the word lines WL0˜WL3 to determine a selected memory cell. Moreover, the controlling circuit can perform a forming action, a program action or a read action on the selected memory cell.

For example, when the word line WL0 is activated and the memory cell 310a is determined as the selected memory cell, the controlling circuit may perform the forming action on the memory cell 310a. For example, by providing a first bias voltage (e.g., +3V) to the source lines SL0a and SL0b of the first source line pair and providing a ground voltage to the bit line BL0, both of the first resistor r1 and the second resistor r2 are in the set state.

According to the embodiment of the invention, the first bias voltage may provide to the source line pair at the same time or sequentially provided to the source lines SL0a and SL0b of the first source line pair. For example, while the ground voltage is provided to the bit line BL0, by sequentially providing the first bias voltage (e.g., +3V) to the source lines SL0a and SL0b of the first source line pair, the first resistor r1 is in the set state firstly and then the second resistor r2 is in the set state.

Moreover, in response to a program action during a program cycle, the controlling circuit may perform a reset action on the memory cell 310a. That is, by providing a second bias voltage (e.g., −3V) to the source lines SL0a and SL0b of the first source line pair and providing a ground voltage to the bit line BL0, both of the first resistor r1 and the second resistor r2 are in a reset state. Or, while the ground voltage is provided to the bit line BL0, by sequentially providing the second bias voltage (e.g., −3V) to the source lines SL0a and SL0b of the first source line pair, the first resistor r1 is in the reset state firstly and then the second resistor r2 is in the reset state.

Alternatively, in response to the program action during the program cycle, the controlling circuit may perform a set action on the memory cell 310a. That is, by applying a third bias voltage (e.g., +3V) to the source lines SL0a and SL0b of the first source line pair and providing a ground voltage to the bit line BL0, both of the first resistor r1 and the second resistor r2 are in the set state. Or, while the ground voltage is provided to the bit line BL0, by sequentially providing the third bias voltage (e.g., +3V) to the source lines SL0a and SL0b of the first source line pair, the first resistor r1 is in the set state firstly and then the second resistor r2 is in the set state.

Moreover, in response to a read action during a read cycle, a read voltage (e.g., 0.1V˜0.5V) is provided to the source lines SL0a and SL0b of the first source line pair, and the ground voltage is provided to the bit line BL0. Consequently, the first resistor r1 generates a first read current to the bit line BL0, and the second resistor r2 generates a second read current to the bit line BL0. Consequently, a superposed read current is received by the bit line BL0. The magnitude of the superposed read current is equal to the sum of the first read current and the second read current. According to the magnitude of the superposed read current, the controlling circuit can realize the storing state (i.e., the set state or the reset state) of the memory cell 310a.

Obviously, in case that both of the first resistor r1 and the second resistor r2 of the memory cell 310a are in the set state, the memory cell 310a issues two read currents to the bit line BL0. That is, the magnitude of the superposed read current is higher. Due to the higher magnitude of the superposed read current, the controlling circuit can judge the storing state of the memory cell 310a more accurately.

FIG. 3C is a schematic circuit diagram illustrating a second exemplary memory cell array with the memory cells of FIG. 3A. As shown in FIG. 3C, the memory cells of the memory cell array 330 are arranged in a 4×4 array. Moreover, the memory cell array 330 is connected with word lines WL0˜WL3, bit lines BL0˜BL3, a first source line pair (SL0a, SL0b), a second source line pair (SL1a, SL01), a third source line pair (SL2a, SL2b), and a fourth source line pair (SL3a, SL3b).

In comparison with the memory cell array 320 of FIG. 3B, every two adjacent source line pairs of the memory cell array 330 have a shared source line. That is, there are only three source lines in every two adjacent source line pairs. Consequently, the layout area of the memory cell array is effectively reduced.

Take the memory cells 310b and 310c as an example. As shown in FIG. 3C, the first source line pair comprises two source lines SL0a and SL0b, the second source line pair comprises two source lines SL1a and SL1b, the third source line pair comprises two source lines SL2a and SL2b, and the fourth source line pair comprises two source lines SL3a and SL3b. Since the source line SL0b of the first source line pair and the source line SL1b of the second source line pair are connected with each other, this shared source line is denoted as “SL0b/SL1b”. That is, the source line SL0b/SL1b indicates both of the source lines SL0b and SL1b. Similarly, the source line SL2b/SL3b indicates both of the source lines SL2b and SL3b.

The select terminal of the memory cell 310b is connected with the word line WL0. The third control terminal of the memory cell 310b is connected with the bit line BL0. The first control terminal of the memory cell 310b is connected with the source line SL0a. The second control terminal of the memory cell 310b is connected with the source line SL0b/SL1b. The select terminal of the memory cell 310c is connected with the word line WL1. The third control terminal of the memory cell 310c is connected with the bit line BL0. The first control terminal of the memory cell 310c is connected with the source line SL1a. The second control terminal of the memory cell 310c is connected with the source line SL0b/SL1b.

The memory cell array 330 is connected with a controlling circuit (not shown). The controlling circuit can active one of the word lines WL0˜WL3 to determine a selected memory cell. Moreover, the controlling circuit can perform a forming action, a program action or a read action on the selected memory cell.

For example, when the word line WL0 is activated and the memory cell 310b is determined as the selected memory cell, the controlling circuit may perform the forming action on the memory cell 310b. For example, by providing a first bias voltage (e.g., +3V) to the source lines SL0a and SL0b (or SL0b/SL1b) and providing a ground voltage to the bit line BL0, both of the first resistor r1 and the second resistor r2 are in the set state.

According to the embodiment of the invention, the first bias voltage may provide to the source line pair at the same time or sequentially provided to the source lines SL0a and SL0b/SL1b of the first source line pair. For example, while the ground voltage is provided to the bit line BL0, by sequentially providing the first bias voltage (e.g., +3V) to the source lines SL0a and SL0b/SL1b of the first source line pair, the first resistor r1 is in the set state firstly and then the second resistor r2 is in the set state.

Moreover, in response to a program action during a program cycle, the controlling circuit may perform a reset action on the memory cell 310b. That is, by providing a second bias voltage (e.g., −3V) to the source lines SL0a and SL0b (or SL0b/SL1b) and providing a ground voltage to the bit line BL0, both of the first resistor r1 and the second resistor r2 are in a reset state. Or, while the ground voltage is provided to the bit line BL0, by sequentially providing the second bias voltage (e.g., −3V) to the source lines SL0a and SL0b/SL1b of the first source line pair, the first resistor r1 is in the reset state firstly and then the second resistor r2 is in the reset state.

Alternatively, in response to the program action during the program cycle, the controlling circuit may perform a set action on the memory cell 310b. That is, by applying a third bias voltage (e.g., +3V) to the source lines SL0a and SL0b (or SL0b/SL1b) and providing a ground voltage to the bit line BL0, both of the first resistor r1 and the second resistor r2 are in the set state. Or, while the ground voltage is provided to the bit line BL0, by sequentially providing the third bias voltage (e.g., +3V) to the source lines SL0a and SL0b/SL1b of the first source line pair, the first resistor r1 is in the set state firstly and then the second resistor r2 is in the set state.

Moreover, in response to a read action during a read cycle, a read voltage (e.g., 0.1V˜0.5V) is provided to the source lines SL0a and SL0b (or SL0b/SL1b), and the ground voltage is provided to the bit line BL0. Consequently, the first resistor r1 generates a first read current to the bit line BL0, and the second resistor r2 generates a second read current to the bit line BL0. Consequently, a superposed read current is received by the bit line BL0. The magnitude of the superposed read current is equal to the sum of the first read current and the second read current. According to the magnitude of the superposed read current, the controlling circuit can realize the storing state (i.e., the set state or the reset state) of the memory cell 310b.

Similarly, when the word line WL1 is activated and the memory cell 310c is determined as the selected memory cell, the controlling circuit may perform the forming action on the memory cell 310c. For example, by providing a first bias voltage (e.g., +3V) to the source lines SL1a and SL1b (or SL0b/SL1b) and providing a ground voltage to the bit line BL0, both of the first resistor r1 and the second resistor r2 are in the set state. Or, while the ground voltage is provided to the bit line BL0, by sequentially providing the first bias voltage (e.g., +3V) to the source lines SL1a and SL0b/SL1b of the second source line pair, the first resistor r1 is in the set state firstly and then the second resistor r2 is in the set state.

Moreover, in response to a program action during a program cycle, the controlling circuit may perform a reset action on the memory cell 310c. That is, by providing a second bias voltage (e.g., −3V) to the source lines SL1a and SL1b (or SL0b/SL1b) and providing a ground voltage to the bit line BL0, both of the first resistor r1 and the second resistor r2 are in a reset state. Or, while the ground voltage is provided to the bit line BL0, by sequentially providing the second bias voltage (e.g., −3V) to the source lines SL1a and SL0b/SL1b of the second source line pair, the first resistor r1 is in the reset state firstly and then the second resistor r2 is in the reset state.

Alternatively, in response to the program action during the program cycle, the controlling circuit may perform a set action on the memory cell 310c. That is, by applying a third bias voltage (e.g., +3V) to the source lines SL01a and SL1b (or SL0b/SL1b) and providing a ground voltage to the bit line BL0, both of the first resistor r1 and the second resistor r2 are in the set state. Or, while the ground voltage is provided to the bit line BL0, by sequentially providing the third bias voltage (e.g., +3V) to the source lines SL1a and SL0b/SL1b of the second source line pair, the first resistor r1 is in the set state firstly and then the second resistor r2 is in the set state.

Moreover, in response to a read action during a read cycle, a read voltage (e.g., 0.1V˜0.5V) is provided to the source lines SL1a and SL1b (or SL0b/SL1b), and the ground voltage is provided to the bit line BL0. Consequently, the first resistor r1 generates a first read current to the bit line BL0, and the second resistor r2 generates a second read current to the bit line BL0. Consequently, a superposed read current is received by the bit line BL0. The magnitude of the superposed read current is equal to the sum of the first read current and the second read current. According to the magnitude of the superposed read current, the controlling circuit can realize the storing state (i.e., the set state or the reset state) of the memory cell 310c.

Obviously, in case that both of the first resistor r1 and the second resistor r2 of the memory cell 310a, 310b or 310c are in the set state, two read currents are issued to the bit line BL0. That is, the magnitude of the superposed read current is higher. Due to the higher magnitude of the superposed read current, the controlling circuit can judge the storing state of the memory cell more accurately.

In the memory cell array 320 of FIG. 3B and the memory cell array 330 of FIG. 3C, the first resistor r1 and the second resistor r2 of each memory cell are programmed into the same storing state during the program cycle. For example, both of the first resistor r1 and the second resistor r2 are in the set state, or both of the first resistor r1 and the second resistor r2 are in the reset state. Moreover, the storing state of the memory cell is realized according to the magnitude of the superposed read current.

FIG. 3D is a schematic circuit diagram illustrating a third exemplary memory cell array with the memory cells of FIG. 3A. As shown in FIG. 3D, the memory cells of the memory cell array 340 are arranged in a 4×4 array. Moreover, the memory cell array 340 is connected with word lines WL0˜WL3, a first bit line pair (BL0a, BL0b), a second bit line pair (BL1a, BL1b), a third bit line pair (BL2a, BL2b), a fourth bit line pair (BL3a, BL3b), and source lines SL0˜SL1.

Take the memory cell 310d as an example. The select terminal of the memory cell 310d is connected with the word line WL0. The third control terminal of the memory cell 310d is connected with the source line SL0. The first control terminal and the second control terminal of the memory cell 310d are respectively connected with the bit lines BL0a and BL0b of the first bit line pair. The connecting relationships between other memory cells and the corresponding lines are similar to the connecting relationship between the memory cell 310d and the corresponding lines, and are not redundantly described herein.

In this embodiment, the memory cell 310d is a differential memory cell. Consequently, the first resistor r1 and the second resistor r2 are programmed to have different storing states during the program cycle. For example, in case that the first resistor r1 is in the set state and the second resistor r2 is in the reset state by the program action, the memory cell 310d has a first storing state. Whereas, in case that the first resistor r1 is in the reset state and the second resistor r2 is in the set state by the program action, the memory cell 310d has a second storing state.

The memory cell array 340 is connected with a controlling circuit (not shown). The controlling circuit can active one of the word lines WL0˜WL3 to determine a selected memory cell. Moreover, the controlling circuit can perform a forming action, a program action or a read action on the selected memory cell.

For example, when the word line WL0 is activated and the memory cell 310d is determined as the selected memory cell, the controlling circuit may perform the forming action on the memory cell 310d. For example, by providing a first bias voltage (e.g., +3V) to the bit lines BL0a and BL0b of the first bit line pair and providing a ground voltage to the source line SL0, both of the first resistor r1 and the second resistor r2 are in the set state.

According to the embodiment of the invention, the first bias voltage may provide to the bit line pair at the same time or sequentially provided to the bit lines BL0a and BL0b of the first bit line pair. For example, while the ground voltage is provided to the source line SL0, by sequentially providing the first bias voltage (e.g., +3V) to the bit lines BL0a and BL0b of the first bit line pair, the first resistor r1 is in the set state firstly and then the second resistor r2 is in the set state.

For programming the memory cell 310d to have the first storing state during a program cycle, the controlling circuit may perform a set action on the first resistor r1 and perform a reset action on the second resistor r2. That is, a third bias voltage (e.g., +3V) is provided to the bit line BL0a of the first bit line pair, a second bias voltage (e.g., −3V) is provided to the bit line BL0b of the first bit line pair, and the ground voltage is provided to the source line SL0. Consequently, the first resistor r1 is in the set state, and the second resistor r2 is in the reset state. Or, while the ground voltage is provided to the source line SL0, the third bias voltage (e.g., +3V) is firstly provided to the bit line BL0a to make the first resistor r1 in the set state, and then the second bias voltage (e.g., −3V) is provided to the bit line BL0b to make the second resistor r2 in the reset state.

Alternatively, for programming the memory cell 310d to have the second storing state during the program cycle, the controlling circuit may perform a reset action on the first resistor r1 and perform a set action on the second resistor r2. That is, the second bias voltage (e.g., −3V) is provided to the bit line BL0a of the first bit line pair, the third bias voltage (e.g., +3V) is provided to the bit line BL0b of the first bit line pair, and the ground voltage is provided to the source line SL0. Consequently, the first resistor r1 is in the reset state, and the second resistor r2 is in the set state. Or, while the ground voltage is provided to the source line SL0, the second bias voltage (e.g., −3V) is firstly provided to the bit line BL0a to make the first resistor r1 in the reset state, and then the third bias voltage (e.g., +3V) is provided to the bit line BL0b to make the second resistor r2 in the set state.

Moreover, in response to a read action during a read cycle, a read voltage (e.g., 0.1V˜0.5V) is provided to the source line SL0a, and the ground voltage is provided to the bit lines BL0a and BL0b of the first bit line pair. Consequently, the first resistor r1 generates a first read current to the bit line BL0a, and the second resistor r2 generates a second read current to the bit line BL0b. By comparing the first read current with the second read current, the controlling circuit realizes the storing state of the memory cell 310d. For example, if the first read current is higher than the second read current, the memory cell 310d has the first storing state. Whereas, if the first read current is lower than the second read current, the memory cell 310d has the second storing state.

In the memory cell array 340 of FIG. 3D, the first resistor r1 and the second resistor r2 of each memory cell are programmed to have different storing states during the program cycle. During the read cycle, the storing state of the memory cell is realized according to the result of comparing the first read current with the second read current.

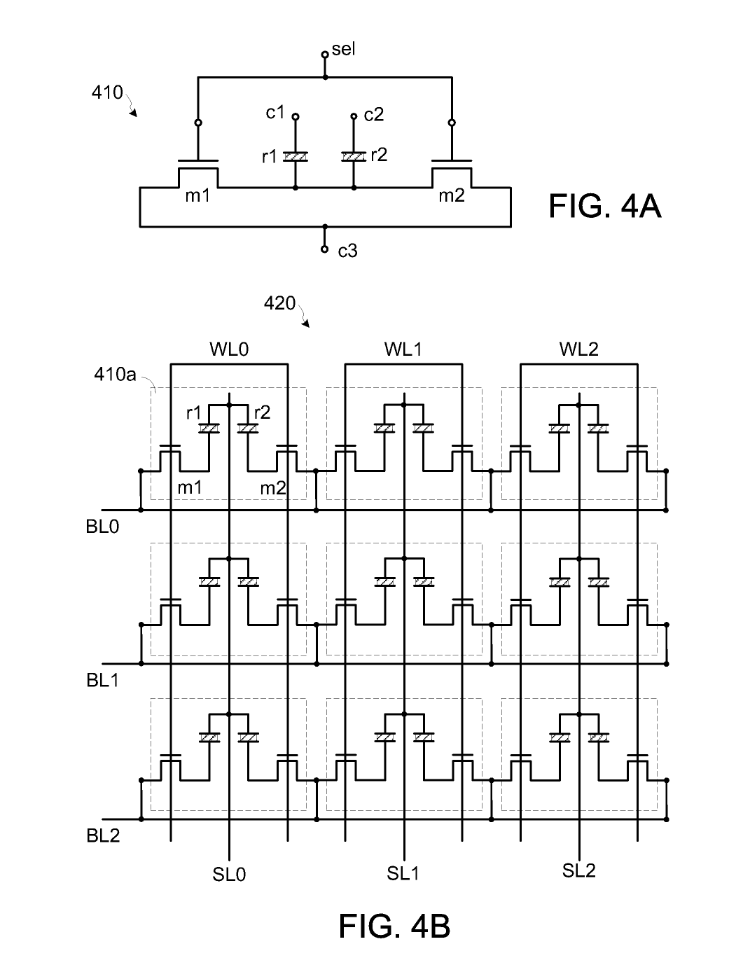

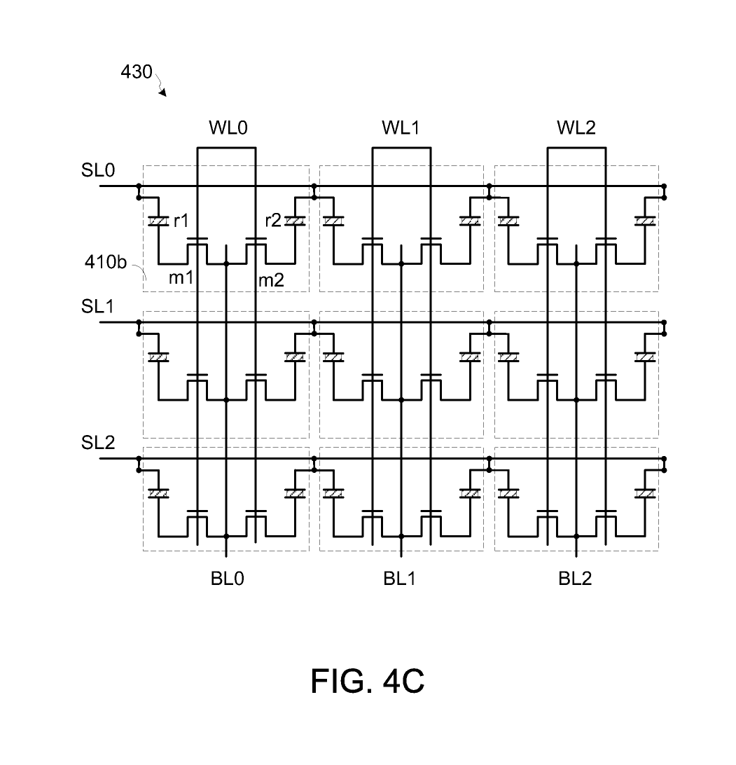

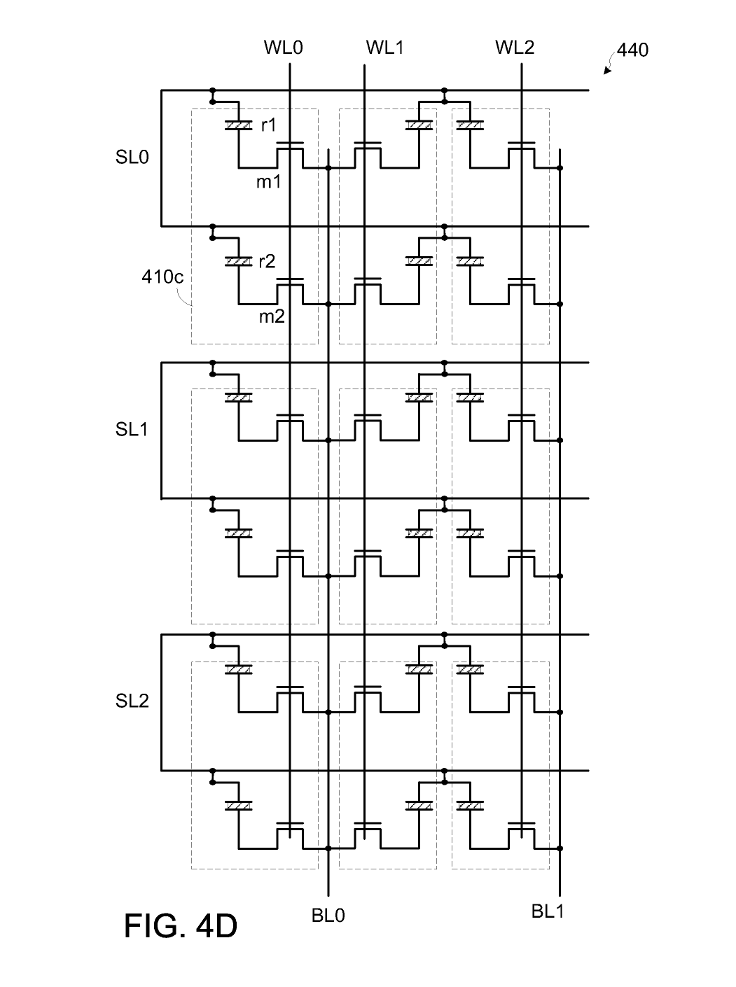

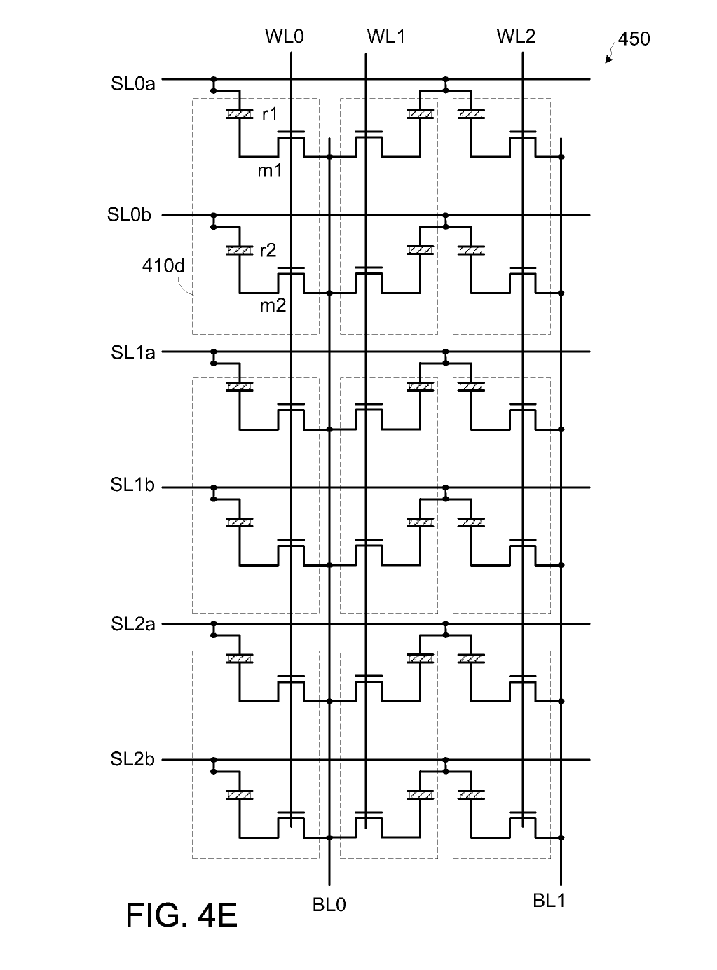

FIG. 4A is a schematic circuit diagram illustrating the structure of a memory cell of a resistive random-access memory according to a second embodiment of the present invention. As shown in FIG. 4A, the memory cell 410 comprises a first select transistor m1, a second select transistor m2, a first resistor r1 and a second resistor r2. A gate terminal of the first select transistor m1 and a gate terminal of the second select transistor m2 are connected with a select terminal sel. A first source/drain terminal of the first select transistor m1 and a first source/drain terminal of the second select transistor m2 are connected with each other, and connected with a third control terminal c3. A second source/drain terminal of the first select transistor m1 and a second source/drain terminal of the second select transistor m2 are connected with each other. The first resistor r1 is connected between a first control terminal c1 and the second source/drain terminal of the first select transistor m1 (and the second select transistor m2). The second resistor r2 is connected between a second control terminal c2 and the second source/drain terminal of the first select transistor m1 (and the second select transistor m2). In this embodiment, the first resistor r1 and the second resistor r2 have the structures of resistive random-access memories.

Moreover, plural memory cells 410 can be combined together as several types of memory cell arrays. The detailed structures of these memory cell arrays will be illustrated as follows.

FIG. 4B is a schematic circuit diagram illustrating a first exemplary memory cell array with the memory cells of FIG. 4A. As shown in FIG. 4B, the memory cells of the memory cell array 420 are arranged in a 3×3 array. Moreover, the memory cell array 420 is connected with word lines WL0˜WL2, bit lines BL0˜BL2, and source lines SL0˜SL2.

Take the memory cell 410a as an example. The select terminal of the memory cell 410a is connected with the word line WL0. The third control terminal of the memory cell 410a is connected with the bit line BL0. Both of the first control terminal and the second control terminal of the memory cell 410a are connected with the source line SL0. The connecting relationships between other memory cells and the corresponding lines are similar to the connecting relationship between the memory cell 410a and the corresponding lines, and are not redundantly described herein.

The memory cell array 420 is connected with a controlling circuit (not shown). The controlling circuit can active one of the word lines WL0˜WL2 to determine a selected memory cell. Moreover, the controlling circuit can perform a forming action, a program action or a read action on the selected memory cell.

For example, when the word line WL0 is activated and the memory cell 410a is determined as the selected memory cell, the controlling circuit may perform the forming action on the memory cell 410a. For example, by providing a first bias voltage (e.g., +3V) to the source line SL0 and providing a ground voltage to the bit line BL0, both of the first resistor r1 and the second resistor r2 are in the set state.

Moreover, in response to a program action during a program cycle, the controlling circuit may perform a reset action on the memory cell 410a. That is, by providing a second bias voltage (e.g., −3V) to the source line SL0 and providing a ground voltage to the bit line BL0, both of the first resistor r1 and the second resistor r2 are in a reset state. Alternatively, in response to the program action during the program cycle, the controlling circuit may perform a set action on the memory cell 410a. That is, by applying a third bias voltage (e.g., +3V) to the source line SL0 and providing a ground voltage to the bit line BL0, both of the first resistor r1 and the second resistor r2 are in the set state.

Moreover, in response to a read action during a read cycle, a read voltage (e.g., 0.1V˜0.5V) is provided to the source line SL0 and the ground voltage is provided to the bit line BL0. Consequently, the first resistor r1 generates a first read current to the bit line BL0, and the second resistor r2 generates a second read current to the bit line BL0. Consequently, a superposed read current is received by the bit line BL0. The magnitude of the superposed read current is equal to the sum of the first read current and the second read current. According to the magnitude of the superposed read current, the controlling circuit can realize the storing state (i.e., the set state or the reset state) of the memory cell 410a.

Obviously, in case that both of the first resistor r1 and the second resistor r2 of the memory cell 410a are in the set state, the memory cell 410a issues two read currents to the bit line BL0. That is, the magnitude of the superposed read current is higher. Due to the higher magnitude of the superposed read current, the controlling circuit can judge the storing state of the memory cell 410a more accurately.

FIG. 4C is a schematic circuit diagram illustrating a second exemplary memory cell array with the memory cells of FIG. 4A. FIG. 4D is a schematic circuit diagram illustrating a third exemplary memory cell array with the memory cells of FIG. 4A. In comparison with the memory cell array of FIG. 4B, the arrangements of the word lines WL0˜WL2, the bit lines BL0˜BL2, and the source lines SL0˜SL2 in the memory cell arrays of FIGS. 4C and 4D are distinguished.

Please refer to the memory cell array 430 of FIG. 4C. The select terminal of the memory cell 410b is connected with the word line WL0. The third control terminal of the memory cell 410b is connected with the bit line BL0. Both of the first control terminal and the second control terminal of the memory cell 410b are connected with the source line SL0. The connecting relationships between other memory cells and the corresponding lines are similar to the connecting relationship between the memory cell 410b and the corresponding lines, and are not redundantly described herein.

Please refer to the memory cell array 440 of FIG. 4D. The select terminal of the memory cell 410c is connected with the word line WL0. The third control terminal of the memory cell 410c is connected with the bit line BL0. Both of the first control terminal and the second control terminal of the memory cell 410c are connected with the source line SL0. The connecting relationships between other memory cells and the corresponding lines are similar to the connecting relationship between the memory cell 410c and the corresponding lines, and are not redundantly described herein.

FIG. 4E is a schematic circuit diagram illustrating a fourth exemplary memory cell array with the memory cells of FIG. 4A. As shown in FIG. 4E, the memory cells of the memory cell array 450 are arranged in a 3×3 array. Moreover, the memory cell array 450 is connected with word lines WL0˜WL2, bit lines BL0˜BL1, a first source line pair (SL0a, SL0b), a second source line pair (SL1a, SL1b) and a third source line pair (SL2a, SL2b).

Take the memory cell 410d as an example. The select terminal of the memory cell 410d is connected with the word line WL0. The third control terminal of the memory cell 410d is connected with the bit line BL0. The first control terminal of the memory cell 410d is connected with the source line SL0a of the first source line pair. The second control terminal of the memory cell 410d is connected with the source line SL0b of the first source line pair. The connecting relationships between other memory cells and the corresponding lines are similar to the connecting relationship between the memory cell 410d and the corresponding lines, and are not redundantly described herein.

The memory cell array 450 is connected with a controlling circuit (not shown). The controlling circuit can active one of the word lines WL0˜WL2 to determine a selected memory cell. Moreover, the controlling circuit can perform a forming action, a program action or a read action on the selected memory cell.

For example, when the word line WL0 is activated and the memory cell 410d is determined as the selected memory cell, the controlling circuit may perform the forming action on the memory cell 410d. For example, by providing a first bias voltage (e.g., +3V) to the source lines SL0a and SL0b of the first source line pair and providing a ground voltage to the bit line BL0, both of the first resistor r1 and the second resistor r2 are in the set state.

According to the embodiment of the invention, the first bias voltage may provide to the source line pair at the same time or sequentially provided to the source lines SL0a and SL0b of the first source line pair. For example, while the ground voltage is provided to the bit line BL0, by sequentially providing the first bias voltage (e.g., +3V) to the source lines SL0a and SL0b of the first source line pair, the first resistor r1 is in the set state firstly and then the second resistor r2 is in the set state.

Moreover, in response to a program action during a program cycle, the controlling circuit may perform a reset action on the memory cell 410d. That is, by providing a second bias voltage (e.g., −3V) to the source lines SL0a and SL0b of the first source line pair and providing a ground voltage to the bit line BL0, both of the first resistor r1 and the second resistor r2 are in a reset state. Or, while the ground voltage is provided to the bit line BL0, by sequentially providing the second bias voltage (e.g., −3V) to the source lines SL0a and SL0b of the first source line pair, the first resistor r1 is in the reset state firstly and then the second resistor r2 is in the reset state.

Alternatively, in response to the program action during the program cycle, the controlling circuit may perform a set action on the memory cell 410a. That is, by applying a third bias voltage (e.g., +3V) to the source lines SL0a and SL0b of the first source line pair and providing a ground voltage to the bit line BL0, both of the first resistor r1 and the second resistor r2 are in the set state. Or, while the ground voltage is provided to the bit line BL0, by sequentially providing the third bias voltage (e.g., +3V) to the source lines SL0a and SL0b of the first source line pair, the first resistor r1 is in the set state firstly and then the second resistor r2 is in the set state.

Moreover, in response to a read action during a read cycle, a read voltage (e.g., 0.1V˜0.5V) is provided to the source lines SL0a and SL0b of the first source line pair and the ground voltage is provided to the bit line BL0. Consequently, the first resistor r1 generates a first read current to the bit line BL0, and the second resistor r2 generates a second read current to the bit line BL0. Consequently, a superposed read current is received by the bit line BL0. The magnitude of the superposed read current is equal to the sum of the first read current and the second read current. According to the magnitude of the superposed read current, the controlling circuit can realize the storing state (i.e., the set state or the reset state) of the memory cell 410d.

Obviously, in case that both of the first resistor r1 and the second resistor r2 of the memory cell 410d are in the set state, the memory cell 410d issues two read currents to the bit line BL0. That is, the magnitude of the superposed read current is higher. Due to the higher magnitude of the superposed read current, the controlling circuit can judge the storing state of the memory cell 410d more accurately.

In the above embodiments, the voltage values of the first bias voltage, the second bias voltage, the third bias voltage and the reading voltage used in the forming action, the reset action, the set action and the read action are presented herein for purpose of illustration and description only. It is noted that these voltage values are not restricted.

From the above descriptions, the present invention provides a memory cell array of resistive random-access memories. The memory cell array comprises at least two resistive random-access memories and at least one switch transistor. Consequently, during the read cycle, the storing state of the memory cell can be judged more accurately.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A memory cell array, comprising:
a first bit line;
a first word line;
a first source line pair; and
a first memory cell, wherein a select terminal of the first memory cell is connected with the first word line, a first control terminal of the first memory cell is connected with a first source line of the first source line pair, a second control terminal of the first memory cell is connected with a second source line of the first source line pair, and a third control terminal of the first memory cell is connected with the first bit line, wherein the first memory cell comprises:
a select transistor comprising a gate terminal, a first source/drain terminal and a second source/drain terminal, wherein the gate terminal of the select transistor is connected with the select terminal of the first memory cell, and the first source/drain terminal of the select transistor is connected with the third control terminal of the first memory cell;
a first resistor, wherein a first terminal of the first resistor is connected with the second source/drain terminal of the select transistor of the first memory cell, and a second terminal of the first resistor is connected with the first control terminal of the first memory cell; and
a second resistor, wherein a first terminal of the second resistor is connected with the second source/drain terminal of the select transistor of the first memory cell, and a second terminal of the second resistor is connected with the second control terminal of the first memory cell.

2. The memory cell array as claimed in claim 1, further comprising:
a second word line;
a second source line pair; and
a second memory cell, wherein a select terminal of the second memory cell is connected with the second word line, a first control terminal of the second memory cell is connected with a first source line of the second source line pair, a second control terminal of the second memory cell is connected with a second source line of the second source line pair, and a third control terminal of the second memory cell is connected with the first bit line, wherein the second memory cell comprises:
a select transistor comprising a gate terminal, a first source/drain terminal and a second source/drain terminal, wherein the gate terminal of the select transistor is connected with the select terminal of the second memory cell, and the first source/drain terminal of the select transistor is connected with the third control terminal of the second memory cell;
a first resistor, wherein a first terminal of the first resistor is connected with the second source/drain terminal of the select transistor of the second memory cell, and a second terminal of the first resistor is connected with the first control terminal of the second memory cell; and
a second resistor, wherein a first terminal of the second resistor is connected with the second source/drain terminal of the select transistor of the second memory cell, and a second terminal of the second resistor is connected with the second control terminal of the second memory cell.

3. The memory cell array as claimed in claim 2, further comprising:
a second bit line; and
a third memory cell, wherein a select terminal of the third memory cell is connected with the first word line, a first control terminal of the third memory cell is connected with the first source line of the first source line pair, a second control terminal of the third memory cell is connected with the second source line of the first source line pair, and a third control terminal of the third memory cell is connected with the second bit line, wherein the third memory cell comprises:
a select transistor comprising a gate terminal, a first source/drain terminal and a second source/drain terminal, wherein the gate terminal of the select transistor is connected with the select terminal of the third memory cell, and the first source/drain terminal of the select transistor is connected with the third control terminal of the third memory cell;
a first resistor, wherein a first terminal of the first resistor is connected with the second source/drain terminal of the select transistor of the third memory cell, and a second terminal of the first resistor is connected with the first control terminal of the third memory cell; and
a second resistor, wherein a first terminal of the second resistor is connected with the second source/drain terminal of the select transistor of the third memory cell, and a second terminal of the second resistor is connected with the second control terminal of the third memory cell.

4. The memory cell array as claimed in claim 3, wherein the second source line of the first source line pair and the second source line of the second source line pair are connected with each other.

5. The memory cell array as claimed in claim 1, wherein after a forming action is performed, both of the first resistor and the second resistor of the first memory cell have a set state.

6. The memory cell array as claimed in claim 5, wherein after a program action is performed, both of the first resistor and the second resistor of the first memory cell have the set state, or both of the first resistor and the second resistor of the first memory cell have a reset state.

7. The memory cell array as claimed in claim 6, wherein while a read action is performed, the first resistor of the first memory cell generates a first read current, and the second resistor of the first memory cell generates a second read current, so that a superposed read current equal to a sum of the first read current and the second read current is outputted to the bit line, wherein a storing state of the first memory cell is determined according to a magnitude of the superposed read current.

8. A memory cell array, comprising:
a first bit line pair;
a first word line;
a first source line; and
a first memory cell, wherein a select terminal of the first memory cell is connected with the first word line, a first control terminal of the first memory cell is connected with a first bit line of the first bit line pair, a second control terminal of the first memory cell is connected with a second bit line of the first bit line pair, and a third control terminal of the first memory cell is connected with the first source line, wherein the first memory cell comprises:
a select transistor comprising a gate terminal, a first source/drain terminal and a second source/drain terminal, wherein the gate terminal of the select transistor is connected with the select terminal of the first memory cell, and the first source/drain terminal of the select transistor is connected with the third control terminal of the first memory cell;
a first resistor, wherein a first terminal of the first resistor is connected with the second source/drain terminal of the select transistor of the first memory cell, and a second terminal of the first resistor is connected with the first control terminal of the first memory cell; and
a second resistor, wherein a first terminal of the second resistor is connected with the second source/drain terminal of the select transistor of the first memory cell, and a second terminal of the second resistor is connected with the second control terminal of the first memory cell.

9. The memory cell array as claimed in claim 8, further comprising:
a second word line;
a second memory cell, wherein a select terminal of the second memory cell is connected with the second word line, a first control terminal of the second memory cell is connected with the first bit line of the first bit line pair, a second control terminal of the second memory cell is connected with the second bit line of the first bit line pair, and a third control terminal of the second memory cell is connected with the first source line, wherein the second memory cell comprises:
a select transistor comprising a gate terminal, a first source/drain terminal and a second source/drain terminal, wherein the gate terminal of the select transistor is connected with the select terminal of the second memory cell, and the first source/drain terminal of the select transistor is connected with the third control terminal of the second memory cell;
a first resistor, wherein a first terminal of the first resistor is connected with the second source/drain terminal of the select transistor of the second memory cell, and a second terminal of the first resistor is connected with the first control terminal of the second memory cell; and
a second resistor, wherein a first terminal of the second resistor is connected with the second source/drain terminal of the select transistor of the second memory cell, and a second terminal of the second resistor is connected with the second control terminal of the second memory cell.

10. The memory cell array as claimed in claim 9, further comprising:
a second bit line pair; and
a third memory cell, wherein a select terminal of the third memory cell is connected with the first word line, a first control terminal of the third memory cell is connected with a first bit line of the second bit line pair, a second control terminal of the third memory cell is connected with a second bit line of the second bit line pair, and a third control terminal of the third memory cell is connected with the first source line, wherein the third memory cell comprises:
a select transistor comprising a gate terminal, a first source/drain terminal and a second source/drain terminal, wherein the gate terminal of the select transistor is connected with the select terminal of the third memory cell, and the first source/drain terminal of the select transistor is connected with the third control terminal of the third memory cell;
a first resistor, wherein a first terminal of the first resistor is connected with the second source/drain terminal of the select transistor of the third memory cell, and a second terminal of the first resistor is connected with the first control terminal of the third memory cell; and
a second resistor, wherein a first terminal of the second resistor is connected with the second source/drain terminal of the select transistor of the third memory cell, and a second terminal of the second resistor is connected with the second control terminal of the third memory cell.

11. The memory cell array as claimed in claim 8, wherein after a forming action is performed, both of the first resistor and the second resistor of the first memory cell have a set state.

12. The memory cell array as claimed in claim 11, wherein after a program action is performed, the first resistor and the second resistor of the first memory cell have the set state and a reset state, respectively, or both of the first resistor and the second resistor of the first memory cell have the reset state and the set state, respectively.

13. The memory cell array as claimed in claim 12, wherein while a read action is performed, the first resistor of the first memory cell generates a first read current to the first bit line of the first bit line pair, and the second resistor of the first memory cell generates a second read current to the second bit line of the first bit line pair, wherein a storing state of the first memory cell is determined according to a result of comparing the first read current with the second read current.

14. A memory cell array, comprising:
a first bit line;
a first word line;
a first source line; and
a first memory cell, wherein a select terminal of the first memory cell is connected with the first word line, a first control terminal of the first memory cell is connected with the first source line, a second control terminal of the first memory cell is connected with the first source line, and a third control terminal of the first memory cell is connected with the first bit line, wherein the first memory cell comprises:
a first select transistor comprising a gate terminal, a first source/drain terminal and a second source/drain terminal, wherein the gate terminal of the first select transistor is connected with the select terminal of the first memory cell, and the first source/drain terminal of the first select transistor is connected with the third control terminal of the first memory cell;
a first resistor, wherein a first terminal of the first resistor is connected with the second source/drain terminal of the first select transistor of the first memory cell, and a second terminal of the first resistor is connected with the first control terminal of the first memory cell;
a second select transistor comprising a gate terminal, a first source/drain terminal and a second source/drain terminal, wherein the gate terminal of the second select transistor is connected with the select terminal of the first memory cell, and the first source/drain terminal of the second select transistor is connected with the third control terminal of the first memory cell; and
a second resistor, wherein a first terminal of the second resistor is connected with the second source/drain terminal of the second select transistor of the first memory cell, and a second terminal of the second resistor is connected with the second control terminal of the first memory cell.

15. The memory cell array as claimed in claim 14, further comprising:
a second word line;
a second source line; and
a second memory cell, wherein a select terminal of the second memory cell is connected with the second word line, a first control terminal of the second memory cell is connected with the second source line, a second control terminal of the second memory cell is connected with the second source line, and a third control terminal of the second memory cell is connected with the first bit line, wherein the second memory cell comprises:
a first select transistor comprising a gate terminal, a first source/drain terminal and a second source/drain terminal, wherein the gate terminal of the first select transistor is connected with the select terminal of the second memory cell, and the first source/drain terminal of the first select transistor is connected with the third control terminal of the second memory cell;
a first resistor, wherein a first terminal of the first resistor is connected with the second source/drain terminal of the first select transistor of the second memory cell, and a second terminal of the first resistor is connected with the first control terminal of the second memory cell;
a second select transistor comprising a gate terminal, a first source/drain terminal and a second source/drain terminal, wherein the gate terminal of the second select transistor is connected with the select terminal of the second memory cell, and the first source/drain terminal of the second select transistor is connected with the third control terminal of the second memory cell; and
a second resistor, wherein a first terminal of the second resistor is connected with the second source/drain terminal of the second select transistor of the second memory cell, and a second terminal of the second resistor is connected with the second control terminal of the second memory cell.

16. The memory cell array as claimed in claim 15, further comprising:
a second bit line; and
a third memory cell, wherein a select terminal of the third memory cell is connected with the first word line, a first control terminal of the third memory cell is connected with the first source line, a second control terminal of the third memory cell is connected with the first source line, and a third control terminal of the third memory cell is connected with the second bit line, wherein the third memory cell comprises:
a first select transistor comprising a gate terminal, a first source/drain terminal and a second source/drain terminal, wherein the gate terminal of the first select transistor is connected with the select terminal of the third memory cell, and the first source/drain terminal of the first select transistor is connected with the third control terminal of the third memory cell;
a first resistor, wherein a first terminal of the first resistor is connected with the second source/drain terminal of the first select transistor of the third memory cell, and a second terminal of the first resistor is connected with the first control terminal of the third memory cell;
a second select transistor comprising a gate terminal, a first source/drain terminal and a second source/drain terminal, wherein the gate terminal of the second select transistor is connected with the select terminal of the third memory cell, and the first source/drain terminal of the second select transistor is connected with the third control terminal of the third memory cell; and
a second resistor, wherein a first terminal of the second resistor is connected with the second source/drain terminal of the second select transistor of the third memory cell, and a second terminal of the second resistor is connected with the second control terminal of the third memory cell.

17. The memory cell array as claimed in claim 14, wherein after a forming action is performed, both of the first resistor and the second resistor of the first memory cell have a set state.

18. The memory cell array as claimed in claim 17, wherein after a program action is performed, both of the first resistor and the second resistor of the first memory cell have the set state, or both of the first resistor and the second resistor of the first memory cell have a reset state.

19. The memory cell array as claimed in claim 18, wherein while a read action is performed, the first resistor of the first memory cell generates a first read current, and the second resistor of the first memory cell generates a second read current, so that a superposed read current equal to a sum of the first read current and the second read current is outputted to the bit line, wherein a storing state of the first memory cell is determined according to a magnitude of the superposed read current.

20. A memory cell array, comprising:
a first bit line;
a first word line;
a first source line pair; and
a first memory cell, wherein a select terminal of the first memory cell is connected with the first word line, a first control terminal of the first memory cell is connected with a first source line of the first source line pair, a second control terminal of the first memory cell is connected with a second source line of the first source line pair, and a third control terminal of the first memory cell is connected with the first bit line, wherein the first memory cell comprises:
a first select transistor comprising a gate terminal, a first source/drain terminal and a second source/drain terminal, wherein the gate terminal of the first select transistor is connected with the select terminal of the first memory cell, and the first source/drain terminal of the first select transistor is connected with the third control terminal of the first memory cell;
a first resistor, wherein a first terminal of the first resistor is connected with the second source/drain terminal of the first select transistor of the first memory cell, and a second terminal of the first resistor is connected with the first control terminal of the first memory cell;
a second select transistor comprising a gate terminal, a first source/drain terminal and a second source/drain terminal, wherein the gate terminal of the second select transistor is connected with the select terminal of the first memory cell, and the first source/drain terminal of the second select transistor is connected with the third control terminal of the first memory cell; and
a second resistor, wherein a first terminal of the second resistor is connected with the second source/drain terminal of the second select transistor of the first memory cell, and a second terminal of the second resistor is connected with the second control terminal of the first memory cell.

21. The memory cell array as claimed in claim 20, further comprising:
a second word line; and
a second memory cell, wherein a select terminal of the second memory cell is connected with the second word line, a first control terminal of the second memory cell is connected with the first source line of the first source line pair, a second control terminal of the second memory cell is connected with the second source line of the first source line pair, and a third control terminal of the second memory cell is connected with the first bit line, wherein the second memory cell comprises:
a first select transistor comprising a gate terminal, a first source/drain terminal and a second source/drain terminal, wherein the gate terminal of the first select transistor is connected with the select terminal of the second memory cell, and the first source/drain terminal of the first select transistor is connected with the third control terminal of the second memory cell;
a first resistor, wherein a first terminal of the first resistor is connected with the second source/drain terminal of the first select transistor of the second memory cell, and a second terminal of the first resistor is connected with the first control terminal of the second memory cell;
a second select transistor comprising a gate terminal, a first source/drain terminal and a second source/drain terminal, wherein the gate terminal of the second select transistor is connected with the select terminal of the second memory cell, and the first source/drain terminal of the second select transistor is connected with the third control terminal of the second memory cell; and
a second resistor, wherein a first terminal of the second resistor is connected with the second source/drain terminal of the second select transistor of the second memory cell, and a second terminal of the second resistor is connected with the second control terminal of the second memory cell.

22. The memory cell array as claimed in claim 21, further comprising:
a second source line pair; and
a third memory cell, wherein a select terminal of the third memory cell is connected with the first word line, a first control terminal of the third memory cell is connected with a first source line of the second source line pair, a second control terminal of the third memory cell is connected with a second source line of the second source line pair, and a third control terminal of the third memory cell is connected with the first bit line, wherein the third memory cell comprises:
a first select transistor comprising a gate terminal, a first source/drain terminal and a second source/drain terminal, wherein the gate terminal of the first select transistor is connected with the select terminal of the third memory cell, and the first source/drain terminal of the first select transistor is connected with the third control terminal of the third memory cell;
a first resistor, wherein a first terminal of the first resistor is connected with the second source/drain terminal of the first select transistor of the third memory cell, and a second terminal of the first resistor is connected with the first control terminal of the third memory cell;
a second select transistor comprising a gate terminal, a first source/drain terminal and a second source/drain terminal, wherein the gate terminal of the second select transistor is connected with the select terminal of the third memory cell, and the first source/drain terminal of the second select transistor is connected with the third control terminal of the third memory cell; and
a second resistor, wherein a first terminal of the second resistor is connected with the second source/drain terminal of the second select transistor of the third memory cell, and a second terminal of the second resistor is connected with the second control terminal of the third memory cell.

23. The memory cell array as claimed in claim 20, wherein after a forming action is performed, both of the first resistor and the second resistor of the first memory cell have a set state.

24. The memory cell array as claimed in claim 23, wherein after a program action is performed, both of the first resistor and the second resistor of the first memory cell have the set state, or both of the first resistor and the second resistor of the first memory cell have a reset state.

25. The memory cell array as claimed in claim 24, wherein while a read action is performed, the first resistor of the first memory cell generates a first read current, and the second resistor of the first memory cell generates a second read current, so that a superposed read current equal to a sum of the first read current and the second read current is outputted to the bit line, wherein a storing state of the first memory cell is determined according to a magnitude of the superposed read current.
